(19) United States
(12) Patent Application Publication
(10) Pub. No.: US 2015/0163924 A1
(43) Pub. Date: Jun. 11, 2015

(54) METHOD OF BONDING ELECTRONIC COMPONENTS AND ELECTRONIC DEVICE USING THE SAME

(71) Applicant: SAMSUNG ELECTRO-MECHANICS CO., LTD., Gyeonggi-Do (KR)

(72) Inventors: Hye Jin CHO, Seongnam-si (KR); Hyo Jin YOON, Yongin-si (KR); Suk Jin HAM, Seoul (KR)

(73) Assignee: SAMSUNG ELECTRO-MECHANICS CO., LTD., Gyeonggi-Do (KR)

(21) Appl. No.: 14/243,431

(22) Filed: Apr. 2, 2014

(30) Foreign Application Priority Data
Dec. 6, 2013 (KR) 10-2013-0151393

(51) Int. Cl. H05K 3/30; H05K 1/18

(52) U.S. Cl. CPC H05K 3/305; H05K 1/181

(57) ABSTRACT

Embodiments of the invention provide a method and device for bonding an electronic component with improved adhesive force. In accordance with at least one embodiment, the method includes preparing a printed circuit board, coating an optical alignment polymer on a bonding region of the printed circuit board, for bonding the electronic component, aligning the optical alignment polymer by irradiating the printed circuit board with UV, coating an adhesive agent on the optical alignment polymer, and mounting the electronic component on the adhesive agent.

### CROSS REFERENCE TO RELATED APPLICATION

This application claims the benefit of and priority under 35 U.S.C. §119 to Korean Patent Application No. KR 10-2013-0151393, entitled “Method of Bonding Electronic Component and Electronic Device Using the Same,” filed on Dec. 6, 2013, which is hereby incorporated by reference in its entirety into this application.

### BACKGROUND

1. Field of the Invention

The present invention relates to a method of bonding an electronic component and an electronic device using the same.

2. Description of the Related Art

Recently, along with the development of miniaturized and slimmed electronic components, an electronic component and a board for mounting the same have also decreased in size.

As an electronic component and a board have decreased in size, a bonding area between the electronic component and the board has proportionally decreased.

However, when an electronic component is bonded to a board, adhesive force depends upon only an adhesive agent in most cases in accordance with current trends, as described generally, for example, in Korean Patent Laid-Open Publication No. 2013-49451. In this case, adhesive force between an electronic component and a board also decreases due to decrease in a bonding area which causes errors.

When a housing component of a camera module is bonded to a board in which a camera sensor is mounted, the same problem arises. Accordingly, errors occur due to insufficient adhesive force between the camera housing component and the board. Accordingly, problems arise in terms of position alignment between components as well as separation between components.

### SUMMARY

Accordingly, embodiments of the present invention are provided to manufacture an electronic device with high reliability by increasing adhesive force between an electronic component and a printed circuit board to reduce errors in terms of separation between electronic components and position alignment.

According to an exemplary embodiment of the present invention, there is provided a method of bonding an electronic component, including preparing a printed circuit board, coating an optical alignment polymer on a mounting region of the printed circuit board for bonding the electronic component, aligning the optical alignment polymer by irradiating the printed circuit board with UV, coating an adhesive agent on the optical alignment polymer, and mounting the electronic component on the adhesive agent.

In accordance with an embodiment of the invention, the electronic component is a housing unit for a camera module.

In accordance with an embodiment of the invention, the optical alignment polymer includes at least one selected from the group consisting of poly(ω(4-chalconyloxy)alkoxyphenylmaleimide), 6-FDA-HAB-Cl, and polysiloxane cinnamate(PSCN).

In accordance with an embodiment of the invention, the UV has a wavelength of 290 to 320 nm.

In accordance with an embodiment of the invention, the method further includes washing using nozzle spray type de-ionized (DI) water prior to the coating of the optical alignment polymer.

In accordance with an embodiment of the invention, the method further includes drying after the washing using nozzle spray type DI water.

In accordance with an embodiment of the invention, the adhesive agent is a 1-liquid type epoxy.

In accordance with an embodiment of the invention, the mounting of the electronic component uses a hot plate cure-attach method.

In accordance with an embodiment of the invention, the optical alignment polymer is coated to a thickness of 0.1 to 2 μm.

According to another exemplary embodiment of the present invention, there is provided an electronic device including a printed circuit board, an optical alignment polymer coated on the printed circuit board and aligned by UV, an adhesive agent coated on the optical alignment polymer, and an electronic component mounted on the adhesive agent.

In accordance with an embodiment of the invention, the electronic component is a housing unit for a camera module.

In accordance with an embodiment of the invention, the optical alignment polymer includes at least one selected from the group consisting of poly(ω(4-chalconyloxy)alkoxyphenylmaleimide), 6-FDA-HAB-Cl, and polysiloxane cinnamate(PSCN).

In accordance with an embodiment of the invention, the adhesive agent is a 1-liquid type epoxy.

Various objects, advantages and features of the invention will become apparent from the following description of embodiments with reference to the accompanying drawings.

### BRIEF DESCRIPTION OF DRAWINGS

These and other features, aspects, and advantages of the invention are better understood with regard to the following Detailed Description, appended Claims, and accompanying Figures. It is to be noted, however, that the Figures illustrate only various embodiments of the invention and are therefore not to be considered limiting of the invention's scope as it may include other effective embodiments as well.

FIG. 1 is a flowchart of a method of bonding an electronic component to a printed circuit board, in accordance with an embodiment of the present invention.

FIG. 2A is a cross-sectional view of a case in which a housing unit for a camera module is mounted on a printed circuit board, in accordance with an embodiment of the present invention.

FIG. 2B is a plan view of a bonding region of a printed circuit board, on which a housing unit for a camera module is mounted, in accordance with an embodiment of the present invention.

FIG. 3 is an enlarged view illustrating an optical alignment principle of an optical alignment polymer, in accordance with an embodiment of the present invention.

FIG. 4 is a cross-sectional view illustrating alignment of an optical alignment polymer of a bonding region of a printed circuit board, in accordance with an embodiment of the present invention.

FIG. 5 is adhesive force measurement graphs of Examples of aligning an optical alignment polymer, in accordance with an embodiment of the present invention, using a UV to bond a housing unit to a printed circuit board, and Comparative Examples using a conventional housing unit bonding method.

### DETAILED DESCRIPTION

Advantages and features of the present invention and methods of accomplishing the same will be apparent by referring to embodiments described below in detail in connection with the accompanying drawings. However, the present invention is not limited to the embodiments disclosed below and may be implemented in various different forms. The embodiments are provided only for completing the disclosure of the present invention and for fully representing the scope of the present invention to those skilled in the art.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. Like reference numerals refer to like elements throughout the specification.

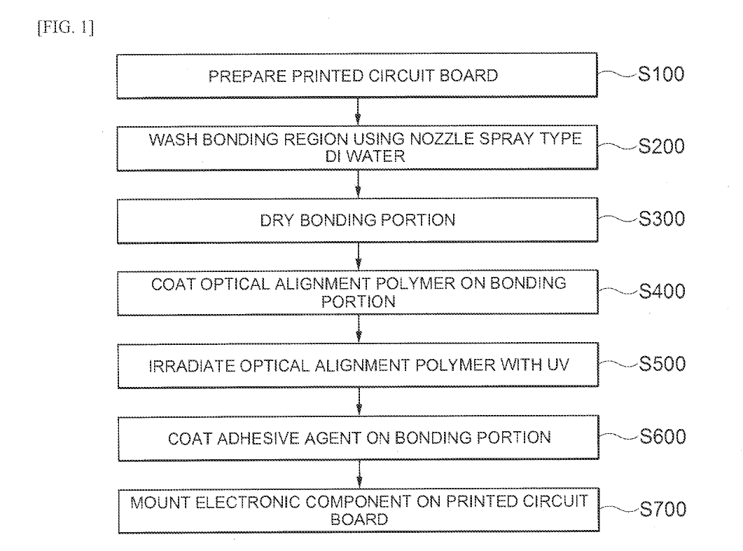

FIG. 1 is a flowchart of a method of bonding an electronic component to a printed circuit board, in accordance with an embodiment of the present invention.

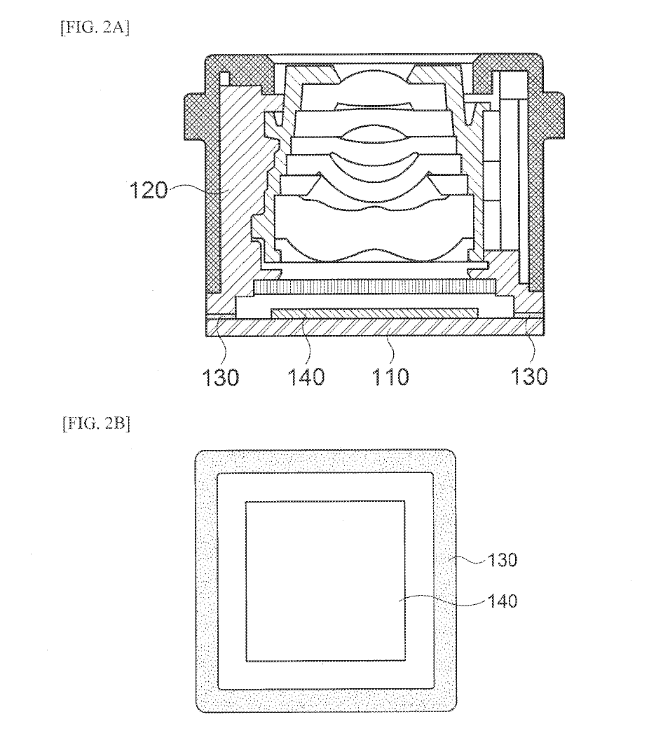

As shown in FIG. 1, a printed circuit board is prepared (S100). Then, a bonding region 130 (FIGS. 2A and 2B) between the printed circuit board and the electronic component is washed by nozzle spray type de-ionized (DI) water (not shown) (S200). Through this washing process, impurities of the bonding region 130 (FIGS. 2A and 2B) are removed to improve the adhesive force in subsequent processes. In this case, the DI water may refer to pure water obtained by restricting electronic conductivity, the number of particulate matter, viable cell count, organic material, etc., and may be frequently used as wash water in a semiconductor manufacturing process and a plating process. Then, a dry process for evaporating the DI water used in the washing process is performed (S300).

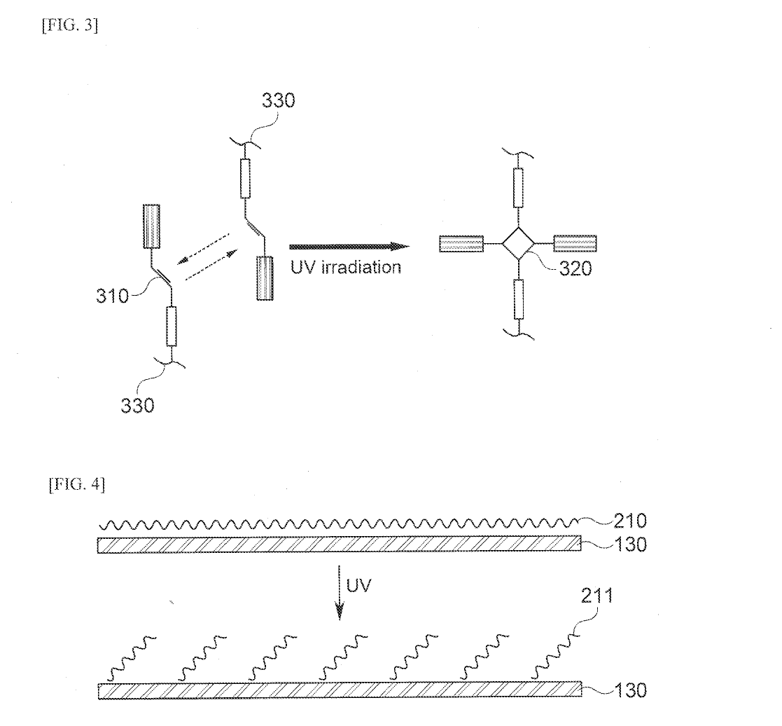

An optical alignment polymer is coated on the bonding region on which the washing and drying processes are performed (S400). In accordance with at least one embodiment of the invention, the polymer is formed to a thickness of 0.04 to 2 μm. When the polymer is formed to a thickness less than 0.04 μm, in accordance with one embodiment, it is difficult to form a uniform polymer layer that is uniformly distributed on an entire portion of the bonding region. When the polymer is formed to a thickness of more than 2.0 μm, this is not helpful in improving adhesive force and thus a thickness exceeding 2.0 μm is not required during a manufacturing process. In addition, the optical alignment polymer refers to a polymer of which main chains are changed in directivity and aligned upon being exposed to light, which will be described with reference to FIG. 3. A double bond 310 of polymer chains is disconnected and changed to a single bond 320 due to UV irradiation to form a new bond and thus an alignment direction of the polymer chain is changed, in accordance with at least one embodiment of the invention.

In accordance with at least one embodiment, examples of the optical alignment polymer include, but are not limited to, poly(ω(4-chalconyloxy)alkoxyphenylmaleimide, 6-FDA-HAB-CI, polysiloxane cinnamate(PSCN), and so on.

In this case, poly(ω(4-chalconyloxy)alkoxyphenylmaleimide) is a polymer represented by Chemical Formula 1 shown below and is prepared by introducing chalcone to a side chain of main chains of maleimide. However, maleimide itself does not polymerize and thus may be polymerized using polystyrene.

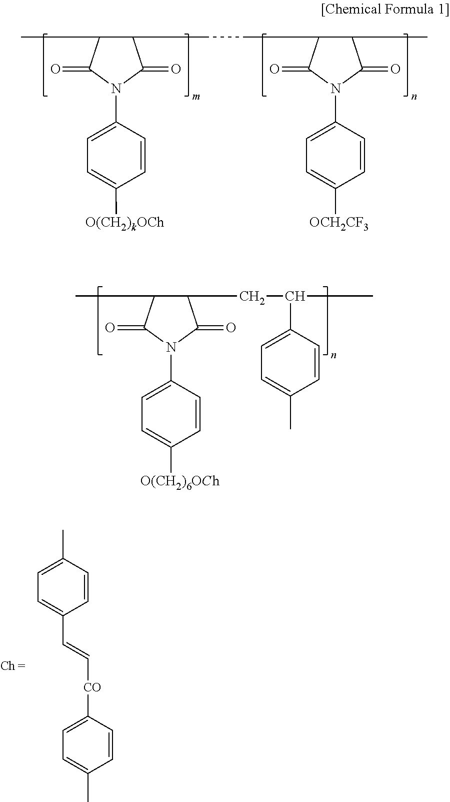

In accordance with at least one embodiment, 6-FDA-HAB-CI is a polymer having a structure represented by Chemical Formula 5 and is prepared by introducing cinnamoly chloride having a structure represented by Chemical Formula 4 below to OH radical of a side chain of main chains composed of HAB(3,3-diamino-4,4-dihydroxybyphrnyl) having a structure represented by Chemical Formula 2 below and 6FDA(4,4-(hexafluoro-isopropylidene)diphthalic anhydride) having a structure represented by Chemical Formula 3 below.

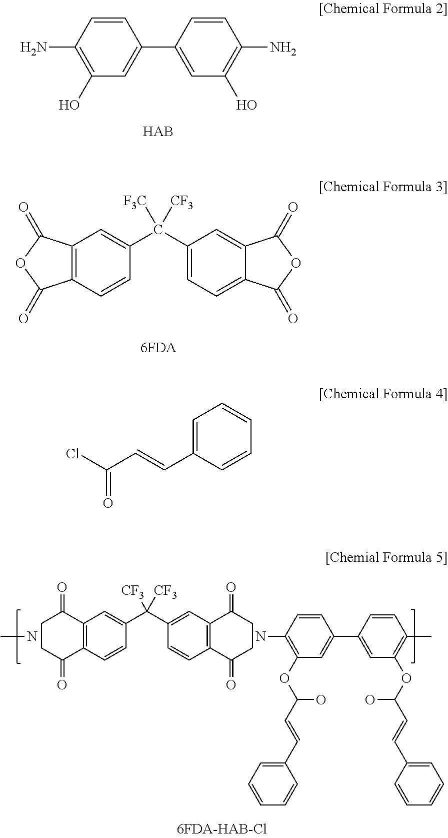

In accordance with at least one embodiment, polysiloxane cinnamate (PSCN) is a polymer having a structure represented according to Chemical Formula 6 below and is prepared by polymerizing a cinnamoly group to a Polysiloxane main chain.

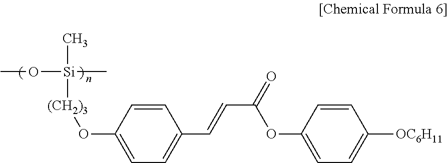

When the aforementioned optical alignment polymers are coated on the bonding region 130 (FIGS. 2A and 2B) of the printed circuit board and is irradiated with UV (S500, FIG. 1), a double bond of a polymer chain 210 (FIG. 4) is disconnected and a new single bond is formed to form an alkyl group 211 (FIG. 4) aligned by UV, as illustrated in FIG. 4. In accordance with at least one embodiment, UV has a wavelength of 200 to 380 nm and uses a region UV-B using a wavelength of 290 to 320 nm, which is mainly used for hardening. However, a wavelength of UV is not limited thereto.

When the optical alignment polymer is irradiated with UV, in accordance with an embodiment of the invention, an alignment degree varies according to an incident angle at which UV is irradiated (see Table 1). When poly(N-(phenyl)maleimide-4-methacryloyl-oxystyryl-4-fluoro phenyl ketone), poly(N-(phenyl)maleimide-4-methacryloyl-oxystyryl-4-methyl phenyl ketone), poly(N-(phenyl)maleimide-4-methacryloyl-oxystyryl-4-propyl phenyl ketone), or the like is used as the optical alignment polymer, about 30° is a maximum alignment degree. Thus, when UV is irradiated at an angle of 30°, an angle for aligning the optical alignment polymer is increased, thereby increasing a bonding area to be very helpful to improve adhesive force. However, since an alignment angle with respect to an incident angle may vary according to each chain structure of various optical alignment polymers, the present invention is not particularly limited to the aforementioned incident angle.

TABLE 1

| | Incident Angle | Alignment Angle |
|---|---|---|
| Poly(N-(phenyl)maleimide-4- | 10° | 0.08° |
| methacryloyl-oxystyryl-4-fluoro | 30° | 0.32° |
| phenyl ketone | 60° | 0.06° |
| Poly(N-(phenyl)maleimide-4- | 10° | 0.04° |
| methacryloyl-oxystyryl-4- | 30° | 0.35° |
| methyl phenyl ketone | 60° | 0.04° |
| Poly(N-(phenyl)maleimide-4- | 10° | 0.08° |
| methacryloyl-oxystyryl-4- | 30° | 0.30° |
| propyl phenyl ketone | 60° | 0.05° |

As a result, in accordance with at least one embodiment, an alkyl group formed on the bonding region of the printed circuit board provides roughness to the bonding region of the printed circuit board to increase a bonding area between the PCB and the electronic component and to form more bonds between the alkyl group and an adhesive agent. Thus, adhesive force between the printed circuit board and an electronic component are reinforced to greatly reduce errors in terms of separating between electronic components or position alignment.

Then, the adhesive agent is coated on the bonding region on which the optical alignment polymer is aligned by UV (S600, FIG. 1). In accordance with at least one embodiment, a 1-liquid type epoxy adhesive agent is mainly used. In accordance with at least one embodiment, the 1-liquid type epoxy adhesive agent uses bisphenol A-type or bisphenol F-type epoxy as a primary material and uses mercaptan as a hardening agent, but the present invention is not limited thereto.

After the adhesive agent is coated, an electronic component is mounted in the bonding region of the printed circuit board (S700, FIG. 1). In this case, the electronic component is mounted on the printed circuit board by pressurizing the electronic component and the printed circuit board at opposite sides by a stack press machine for one minute at a temperature of 100° C. via hot plate curing on a hot plate having built therein a heater.

According to an embodiment of the present invention, in order to check a surface adhesive force reinforcement effect, Example of mounting a camera housing unit on a printed circuit board using an optical alignment polymer and Comparative Example of mounting a camera housing unit on a printed circuit board in a conventional bonding manner are prepared and surface adhesive forces of Example and Comparative Example are compared.

### Example

### Which Uses an Optical Alignment Polymer

(1) Preparation of Optical Alignment Polymer

35 ml of solvent, methyl ethyl ketone (MEK), 0.01 mol of X-substituted 4-meth-acryloyloxystyryl-4′-X-phenyl ketone, and 0.01 mol of N-(phenyl)maleimide are put into a flask at a temperature of 70° C., and are stirred and dissolved. Then, while a temperature of the flask is maintained to 70° C., 1 mol % of azobisisobutyronitrile (AIBN) as an initiator is added, stirred, and polymerized in an N₂ atmosphere. Time for polymerization is 8 to 10 hours. After the polymerization reaction is terminated, precipitating and filtering are performed in methanol three times and the resultant is dried in a vacuum oven for 48 hours to obtain an optical alignment polymer as white powders.

The obtained optical alignment polymer has a structure represented by Chemical Formula 7 below. According to an X substituent, poly(N-(phenyl)maleimide-4-methacryloyl-oxystyryl-4-fluoro phenyl ketone), poly(N-(phenyl)maleimide-4-methacryloyl-oxystyryl-4-methyl phenyl ketone), poly(N-(phenyl)maleimide-4-methacryloyl-oxystyryl-4-propyl phenyl ketone), poly(N-(phenyl)maleimide-4-methacryloyl-oxystyryl-4-pentyl phenyl ketone), or poly(N-(phenyl)maleimide-4-methacryloyl-oxystyryl-4-heptyl phenyl ketone) may be obtained.

According to the present embodiment, a methyl group is used as an X substituent and thus poly(N-(phenyl)maleimide-4-methacryloyl-oxystyryl-4-methyl phenyl ketone) is obtained.

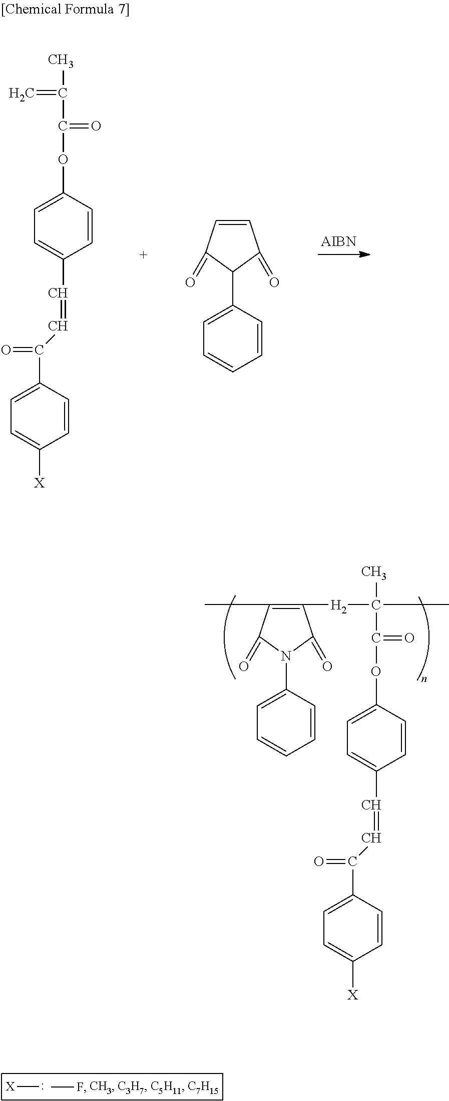

(2) Preparation of Measurement Test Piece

First, a printed circuit board having a size of 8.5 mm*8.5 mm is prepared and then a bonding region (a bonding line width of 0.3 mm) of a camera housing unit is washed by DI water and is dried. Then, 5 wt % of the aforementioned prepared optical alignment polymer (poly(N-(phenyl)maleimide-4-methacryloyl-oxystyryl-4-methyl phenyl ketone)) is added to a solution formed by mixing 2-acetoxy-1-methoxypropane and butylolactane in a ratio of 1:2 and is dissolved, and the resultant is coated to a thickness of 0.7 μm on a bonding region (a bonding line width of 0.3 mm) of a camera housing unit by a screen printing device.

After the optical alignment polymer is coated, the resultant is dried at a temperature of 70° C. and is irradiated with UV to align a polymer coated on the bonding region. Then, 1-liquid type epoxy adhesive agent is coated on the bonding region (i.e., a bonding line width of 0.3 mm) of the camera housing unit to bond the housing unit onto the printed circuit board. Then, the resultant is cure-attached on a hot plate for one minute at a temperature of 120° C.

In Example, four test pieces are prepared in order to reduce measurement errors.

(3) Method of Measuring Adhesive Force

Adhesive force between a printed circuit board and a housing unit is measured by, for example, a DAGE-4000 bond tester available from Nordson. The measurement is performed on the aforementioned four prepared test pieces.

### Comparative Example

### Mounting of Camera Housing Using a Conventional Method

(1) Preparation of Measurement Test Piece

First, a printed circuit board having a size of 8.5 mm*8.5 mm is prepared and then a bonding region (a bonding line width of 0.3 mm) of a camera housing unit is washed by DI water and is dried. Then, a 1-liquid type epoxy agent is coated on the bonding region (a bonding line width of 0.3 mm) of the camera housing unit to bond the housing unit onto the printed circuit board. Then, the resultant is cure-attached on a hot plate for one minute at a temperature of 120° C.

In Comparative Example, four test pieces were prepared using the same method as in Example in order to reduce measurement errors.

(2) Method of Measuring Adhesive Force

Adhesive force between a printed circuit board and a housing unit is measured by, for example, a DAGE-4000 bond tester available from Nordson. The measurement is performed on the aforementioned four prepared test pieces.

Measurement Result of Adhesive Force

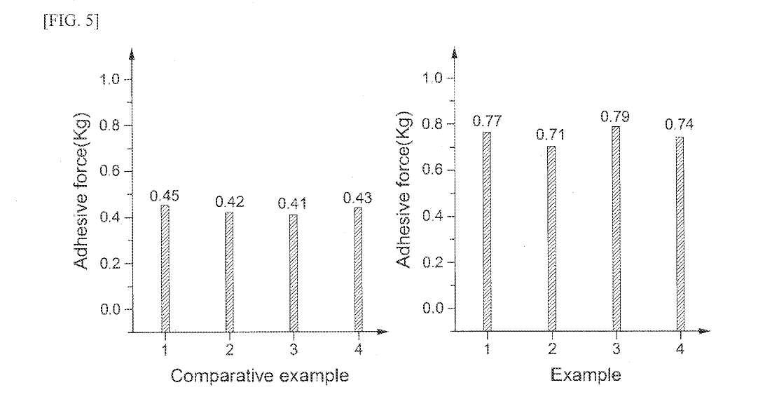

FIG. 5 is adhesive force measurement graphs of Examples of aligning an optical alignment polymer according to the present invention using a UV to bond a housing unit to a printed circuit board and Comparative Examples using a conventional housing unit bonding method. Examples have adhesive force of 0.71 to 0.79 kg and Comparative Examples have adhesive force of 0.41 to 0.45 kg. Thus, it may be seen that embodiments of the present invention have excellent adhesive force compared with Comparative Examples.

In a method of bonding an electronic component according to an embodiment of the present invention, when the electronic component is mounted on a printed circuit board, a bonding area is increased by applying an optical alignment polymer to a bonding region between the electronic component and the printed circuit board, thereby increasing adhesive force between the electronic component and the printed circuit board.

Terms used herein are provided to explain embodiments, not limiting the present invention. Throughout this specification, the singular form includes the plural form unless the context clearly indicates otherwise. When terms “comprises” and/or “comprising” used herein do not preclude existence and addition of another component, step, operation and/or device, in addition to the above-mentioned component, step, operation and/or device.

Embodiments of the present invention may suitably comprise, consist or consist essentially of the elements disclosed and may be practiced in the absence of an element not disclosed. For example, it can be recognized by those skilled in the art that certain steps can be combined into a single step.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

The singular forms “a,” “an,” and “the” include plural referents, unless the context clearly dictates otherwise.

As used herein and in the appended claims, the words “comprise,” “has,” and “include” and all grammatical variations thereof are each intended to have an open, non-limiting meaning that does not exclude additional elements or steps.

As used herein, the terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “in one embodiment” herein do not necessarily all refer to the same embodiment.

Ranges may be expressed herein as from about one particular value, and/or to about another particular value. When such a range is expressed, it is to be understood that another embodiment is from the one particular value and/or to the other particular value, along with all combinations within said range.

Although the present invention has been described in detail, it should be understood that various changes, substitutions, and alterations can be made hereupon without departing from the principle and scope of the invention. Accordingly, the scope of the present invention should be determined by the following claims and their appropriate legal equivalents.

What is claimed is:

1. A method of bonding an electronic component, the method comprising:
preparing a printed circuit board;
coating an optical alignment polymer on a bonding region of the printed circuit board for bonding the electronic component;
aligning the optical alignment polymer by irradiating the printed circuit board with UV;
coating an adhesive agent on the optical alignment polymer; and
mounting the electronic component on the adhesive agent.

2. The method according to claim 1, wherein the electronic component is a housing unit for a camera module.

3. The method according to claim 1, wherein the optical alignment polymer is at least one selected from the group consisting of poly(ω(4-chalconyloxy)alkoxyphenylmaleimide), 6-FDA-HAB-Cl, and polysiloxane cinnamate (PSCN).

4. The method according to claim 1, wherein the UV has a wavelength of 290 to 320 nm.

5. The method according to claim 1, further comprising:
washing using nozzle spray type de-ionized (DI) water prior to the coating of the optical alignment polymer.

6. The method according to claim 5, further comprising:
drying after the washing using nozzle spray type DI water.

7. The method according to claim 1, wherein the adhesive agent is a 1-liquid type epoxy.

8. The method according to claim 1, wherein the mounting of the electronic component uses a hot plate cure-attach method.

9. The method according to claim 1, wherein the optical alignment polymer is coated to a thickness of 0.04 to 2 μm.

10. An electronic device comprising:
a printed circuit board;
an optical alignment polymer coated on a bonding region of the printed circuit board for bonding an electronic component, and aligned by UV;
an adhesive agent coated on the optical alignment polymer; and
an electronic component mounted on the adhesive agent.

11. The electronic device according to claim 10, wherein the electronic component is a housing unit for a camera module.

12. The electronic device according to claim 10, wherein the optical alignment polymer is at least one selected from the group consisting of poly(ω(4-chalconyloxy)alkoxyphenylmaleimide), 6-FDA-HAB-Cl, and polysiloxane cinnamate (PSCN).

13. The electronic device according to claim 10, wherein the adhesive agent is 1-liquid type epoxy.
